(19) United States
(12) Patent Application Publication
(10) Pub. No.: US 2026/0206258 A1
(43) Pub. Date: Jul. 16, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Shih-Hao Lai, Hsinchu (TW); Chung-Wei Hsu, Hsinchu County (TW); Lung-Kun Chu, New Taipei City (TW); Kuo-Cheng CHIANG, Hsinchu County (TW); Chih-Hao Wang, Hsinchu County (TW)

(73) Assignee: Taiwan Semiconductor Manufacturing Company, Ltd., Hsinchu (TW)

(21) Appl. No.: 19/015,676

(22) Filed: Jan. 10, 2025

(51) Int. Cl. H10D 30/67; H10D 30/00; H10D 30/01; H10D 30/43; H10D 30/69; H10D 62/10; H10D 84/01; H10D 84/83

(52) U.S. Cl. CPC H10D 30/6735; H10D 30/014; H10D 30/0191; H10D 30/43; H10D 30/502; H10D 30/791; H10D 62/121; H10D 84/0128; H10D 84/013; H10D 84/832

(57) ABSTRACT

A semiconductor device and method of forming the same are provided. Semiconductor layers are formed and vertically stacked over a protruding fin of a substrate. Source/drain regions are formed on the substrate and at opposite sides of semiconductor layers. A composite dielectric layer is formed on and around the semiconductor layers. A cap layer is formed on and around the composite dielectric layer to cause a compressive stress within the semiconductor layers in a thickness direction (Szz) of the semiconductor layers and a tensile stress within the semiconductor layers in a length direction (Sxx) of the semiconductor layers. A gate electrode is formed on the cap layer.

### BACKGROUND

To increase the speed of transistors, the transistors such as gate all-around (GAA) transistors are being researched and implemented.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 8B are schematic cross-sectional views schematically illustrate various stages of a process for fabricating a Gate All-Around (GAA) transistor and contact plugs in accordance with some embodiments of the present disclosure.

FIG. 9A through FIG. 12B are schematic cross-sectional views schematically illustrate various stages of a process for fabricating a Gate All-Around (GAA) transistor and contact plugs in accordance with some embodiments of the present disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device and a method of forming the semiconductor device are provided. The semiconductor device includes semiconductor layers (referred to as channel layers) vertically stacked a protruding fin of a substrate, a composite stack wrapping around the semiconductor layers, and a gate electrode disposed on the composite stack and wrapping around the semiconductor layers. The composite stack includes a cap layer sandwiched between the semiconductor layers and the gate electrode. The cap layer applies a strain to the channel layers, which compensates the strain defects of source/drain region and enhances mobility for N-type FET (NFET). As a result, the performance of the semiconductor device is improved.

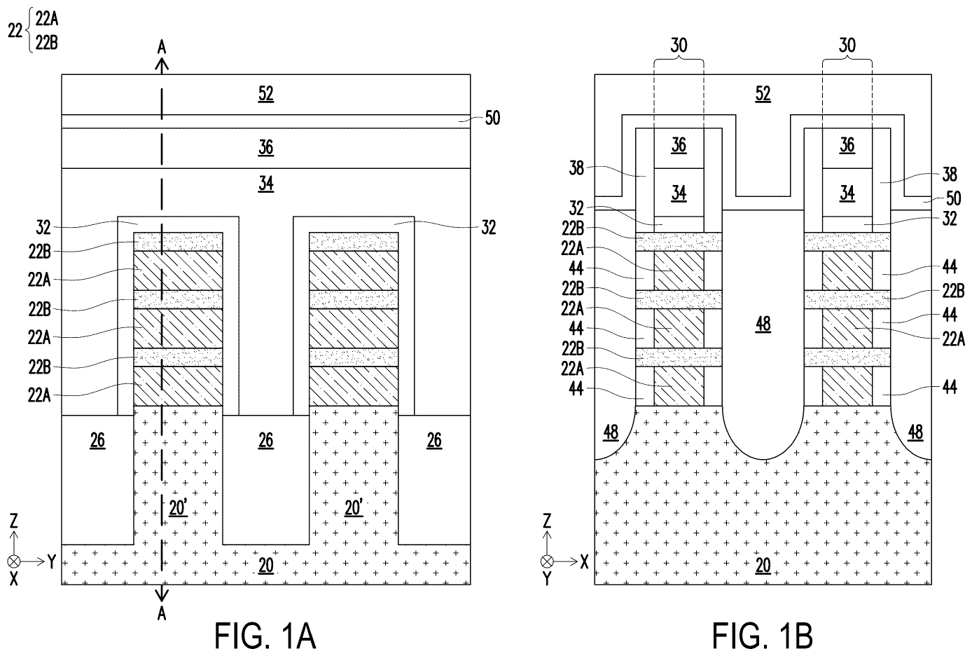

FIG. 1A through FIG. 8B are schematic cross-sectional views schematically illustrate various stages of a process for fabricating a Gate All-Around (GAA) transistor and contact plugs in accordance with some embodiments of the present disclosure.

Referring to FIG. 1A and FIG. 1B, FIG. 1B illustrates the cross-sectional view of line A-A in FIG. 1A. In some embodiments, a substrate 20 is provided. In some embodiments, the substrate 20 is a semiconductor substrate. For example, semiconductor substrate includes a silicon substrate, a silicon germanium (SiGe) substrate, or the like, while other substrates and/or structures, such as semiconductor-on-insulator (SOI), strained SOI, silicon germanium on insulator, or the like, could be used. In some embodiments, the substrate 20 is doped as a p-type semiconductor. In some embodiments, the substrate 20 is doped as an n-type semiconductor.

Referring to FIG. 1A and FIG. 1B, first semiconductor layers 22A and second semiconductor layers 22B are alternately stacked on the substrate 20 and form a multilayer on the substrate 20, then photolithography processes are performed to form protruding fins 20′ protruding from the substrate 20 and multilayer stacks 22 on the substrate 20, shown in FIG. 1A. In some embodiments, a lowest first semiconductor layer 22A is formed on and in contact with the substrate 20 or the protruding fins 20′. In some embodiments, the first semiconductor layers 22A (referred to as sacrificial layers) are formed of a first semiconductor material, and the second semiconductor layers 22B are formed of a second semiconductor material different from the first semiconductor material.

In some embodiments, the first semiconductor material of the first semiconductor layers 22A is or includes silicon germanium (SiGe), germanium (Ge), silicon (Si), gallium arsenide (GaAs), indium antimonide (InSb), gallium antimonide (GaSb), indium aluminium arsenide (InAlAs), indium gallium arsenide (InGaAs), gallium antimonide phosphide (GaSbP), gallium arsenide antimonide (GaAsSb), or the like. In some embodiments, the first semiconductor layers 22A (for example, SiGe) are formed through any suitable epitaxial growth process.

In some embodiments, once the first semiconductor layer 22A has been formed over substrate 20, a second semiconductor layer 22B is formed on the first semiconductor layer 22A, and the first semiconductor layers 22A and the second semiconductor layers 22B are sequentially formed and stacked in alternation. In some embodiments, the second semiconductor layers 22B are formed of or include the second semiconductor material such as Si, SiGe, Ge, GaAs, InSb, GaSb, InAlAs, InGaAs, GaSbP, GaAsSb, or combinations thereof. In some embodiments, the second semiconductor layers 22B (for example, crystalline silicon) are formed through any suitable epitaxial growth process. The second semiconductor material is different from the first semiconductor material of first semiconductor layers 22A. In some embodiments, the first semiconductor layer 22A includes silicon germanium, the second semiconductor layer 22B includes silicon. The lattice constant of crystalline silicon, having a diamond cubic crystal structure, is approximately 5.43 Å.

In some embodiments, the second semiconductor layer 22B is epitaxially grown on the first semiconductor layer 22A using a deposition technique similar to that is used to form the first semiconductor layer 22A. In some embodiments, the second semiconductor layer 22B is formed to a similar thickness to that of the first semiconductor layer 22A. In some embodiments, the second semiconductor layer 22B may also be formed to a thickness that is different from the first semiconductor layer 22A.

Referring to FIG. 1B, shallow trench isolation (STI) regions 26 are formed on the substrate 20, and disposed beside and wrap the protruding fins 20′. In some embodiments, the STI regions 26 include a dielectric material. For example, the dielectric material is formed using flowable chemical vapor deposition (FCVD), spin-on coating, high density plasma chemical vapor deposition (HDPCVD), or the like. In some embodiments, a planarization process such as a chemical mechanical polish (CMP) process or a mechanical grinding process may then be performed to level the top surface of the dielectric material, and the remaining portions of the dielectric material are the STI regions 26.

Referring to FIG. 1B, the STI regions 26 are then recessed, so that the multilayer stacks 22 and top of protruding fins 20′ are revealed. In some embodiments, the recessing of STI regions 26 is performed through a dry etching process. For example, NF₃ and NH₃ are used as the etching gases. During the etching process, plasma may be generated. Argon may also be included. In alternative embodiments, the recessing of STI regions 26 is performed through a wet etching process. For example, the etching chemical includes HF.

Referring to FIG. 1A, dummy gate stacks 30 including dummy gate dielectrics 32, dummy gate electrodes 34, and the hard mask layer 36 are formed on top surfaces and sidewalls of the multilayer stacks 22. Referring to FIG. 1B, the dummy gate stacks 30 and gate spacers 38 are formed on the top surfaces of the multilayer stacks 22.

Referring to FIG. 1A and FIG. 1B, the dummy gate dielectrics 32 are formed on the multilayer stacks 22, and the dummy gate electrodes 34 over dummy gate dielectrics 32. In some embodiments, the dummy gate dielectrics 32 is formed by oxidizing the surface portions of the multilayer stacks 22 and the protruding fins 20′ to form oxide layers, or by depositing a dielectric layer such as a silicon oxide layer. In some embodiments, the dummy gate electrodes 34 is formed by using polysilicon or amorphous silicon, and other materials such as amorphous carbon.

Referring to FIG. 1A and FIG. 1B, the hard mask layer 36 is formed on the dummy gate electrode 34. In some embodiments, the hard mask layer 36 is formed of silicon nitride, silicon oxide, silicon carbo-nitride, silicon oxy-carbo nitride, or multilayers thereof. In some embodiments, the dummy gate stacks 30 cross over the multilayer stacks 22, the protruding fins 20′ and the STI regions 26 between the protruding fins 20′ from a top view. For example, the dummy gate stacks 30 have lengthwise directions perpendicular to the lengthwise directions of the multilayer stacks 22 and the protruding fins 20′. The formation of dummy gate stacks 30 includes forming a dummy gate dielectric layer, depositing a dummy gate electrode layer over the dummy gate dielectric layer, depositing one or more hard mask layers, and then patterning the formed layers through one or more pattering process.

Referring to FIG. 1B, gate spacers 38 are formed on sidewalls of the dummy gate stacks 30. In some embodiments, the gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. In some embodiments, the formation process of gate spacers 38 may include depositing one or more dielectric layers, and then performing one or more anisotropic etching processes on the dielectric layer(s). The remaining portions of the dielectric layer(s) are gate spacers 38.

Referring to FIG. 1B, after the gate spacers 38 are formed, recesses (not shown) for forming source/drain regions 48 are formed between the multilayer stacks 22. In some embodiments, the formation of the recesses includes performing an etching process to remove the portions of the multilayer stacks 22 that are not overlapped with and not directly underlying dummy gate stacks 30 and gate spacers 38. For example, a dry etch process is performed using C₂F₆, CF₄, SO₂, the mixture of HBr, Cl₂, and O₂, the mixture of HBr, Cl₂, O₂, and CH₂F₂, or the like. In some embodiments, the etching process includes anisotropic etching process.

Referring to FIG. 1B, after the recesses are formed, the first semiconductor layers 22A (referred to as sacrificial layers) are laterally recessed to form lateral recesses for forming inner spacers 44, which are recessed from the edges of the respective overlying and underlying the second semiconductor layers 22B. In some embodiments, the lateral recessing of the first semiconductor layers 22A is formed by a wet etching process using an etchant that is more selective to the material (for example, silicon germanium (SiGe)) of the first semiconductor layers 22A than the material (for example, silicon (Si)) of the second semiconductor layers 22B and substrate 20. For example, the first semiconductor layers 22A are formed of silicon germanium and the second semiconductor layers 22B are formed of silicon, the wet etching process is performed using an etchant such as hydrochloric acid (HCl). In alternative embodiments, the lateral recessing of the first semiconductor layers 22A is performed through an isotropic dry etching process or a combination of a dry etching process and a wet etching process.

Referring to FIG. 1B, the inner spacers 44 are formed in the lateral recesses. The inner spacers 44 act as isolation features between subsequently formed source/drain regions and a gate structure. In some embodiments, the inner spacers 44 include a material such as silicon nitride or silicon oxynitride, although any suitable material, such as low-dielectric constant (low-k) materials having a k-value less than about 3.5, may be utilized. In some embodiments, the formation process includes depositing a conformal dielectric layer and then trimming the conformal dielectric layer. For example, the inner spacer layer is deposited by a conformal deposition process, such as chemical vapor deposition (CVD), atomic layer deposition (ALD), or the like. The inner spacer layer is then be anisotropically etched to form the inner spacers 44.

Referring to FIG. 1B, although the inner sidewalls and the outer sidewalls of the inner spacers 44 are schematically illustrated as being straight in FIG. 1B, the inner sidewalls of the inner spacers 44 may be convex, and the outer sidewalls of the inner spacers 44 may be concave or convex. In some embodiments, the inner spacers 44 are used to prevent the damage to subsequently formed source/drain regions, which damage is caused by subsequent etching processes for forming replacement gate structures.

Referring to FIG. 1B, after the inner spacers 44 are formed, the source/drain regions 48 are formed in the recesses between the multilayer stacks 22. In some embodiments, the source/drain regions 48 include semiconductor material. In some embodiments, the formation of the source/drain regions 48 includes performing an epitaxy process. For example, the source/drain regions 48 are epitaxially grown from the second semiconductor layers 22B or from the substrate 20. In some embodiments, transistor is a p-type transistor or an n-type transistor, and a p-type or an n-type impurity is in-situ doped with the proceeding of the epitaxy process. For example, when the transistor is a p-type transistor, silicon germanium boron (SiGeB), silicon boron (SiB), or the like is grown. Conversely, when the transistor is an n-type transistor, silicon phosphorous (SiP), silicon carbon phosphorous (SiCP), or the like is grown. In alternative embodiments, after the epitaxy process, the source/drain regions 48 are further implanted with a p-type or an n-type impurity to form source and drain regions.

Referring to FIG. 1A and FIG. 1B, CESL 50 are formed on hard mask layer 36, the source/drain regions 48, the gate spacers 38 and the dummy gate stacks 30. In some embodiments, the CESL 50 is formed of silicon oxide, silicon nitride, silicon carbo-nitride, or the like, and is formed using CVD, ALD, or the like.

Referring to FIG. 1A and FIG. 1B, an ILD 52 are formed on the CESL 50. The ILD 52 is formed of a dielectric material. For example, the dielectric material includes a silicon-oxide based material such as silicon oxide, Phospho-Silicate Glass (PSG), Boro-Silicate Glass (BSG), Boron-Doped Phospho-Silicate Glass (BPSG), Undoped Silicate Glass (USG), or the like. In some embodiments, the formation of ILD 52 includes forming the dielectric material by FCVD, spin-on coating, CVD, or any other suitable deposition method.

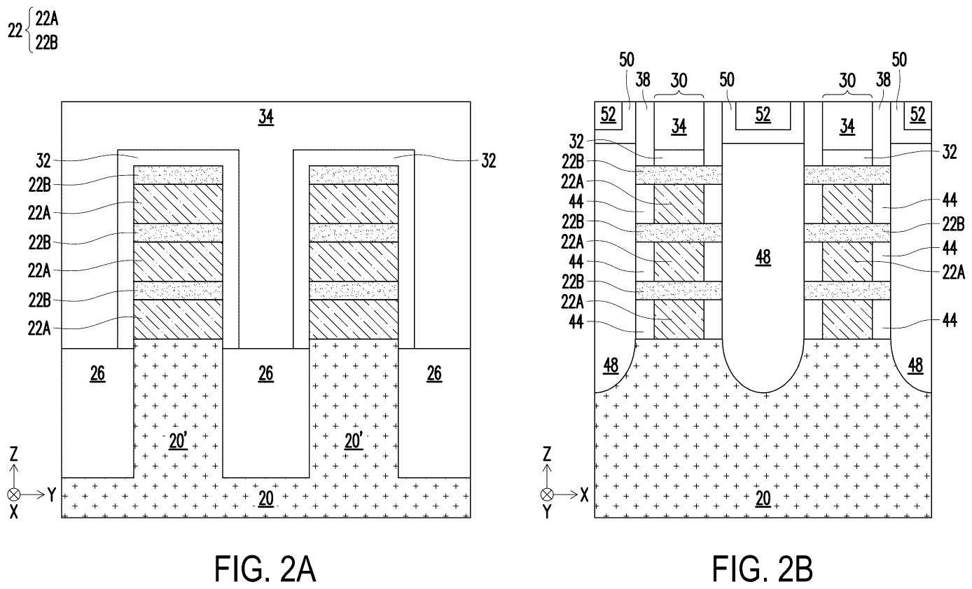

Referring to FIG. 2A and FIG. 2B, a planarization process such as a CMP process or a mechanical grinding process is performed to level the top surface of the ILD 52. In some embodiments, the planarization process also removes the CESL 50 and the hard masks 36 to reveal the dummy gate electrodes 34, as shown in FIG. 2A. In some embodiments, the planarization process removes portions of the CESL 50 and the gate spacers 38, and the hard masks 36 to reveal the dummy gate electrodes 34. The top surfaces of the dummy gate electrodes 34, the gate spacers 38, the CESL 50 and the ILD 52 are level, as shown in FIG. 2B.

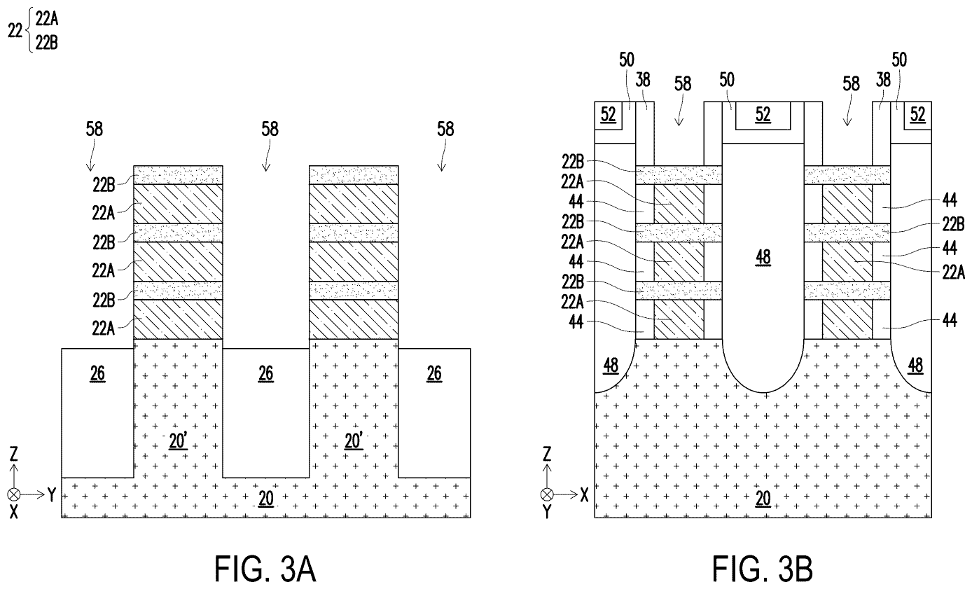

Referring to FIG. 3A and FIG. 3B, the dummy gate electrodes 34 and dummy gate dielectrics 32 are removed by performing one or more etching processes, so that recesses 58 are formed between the gate spacers 38 and the topmost second semiconductor layers 22B. In some embodiments, the dummy gate electrodes 34 and the dummy gate dielectrics 32 are removed through an anisotropic dry etch process. For example, the etching process is performed using reaction gas(es) that selectively etch the dummy gate electrodes 34 at a faster rate than the ILD 52. Each recess 58 reveal multilayer stacks 22, as shown in FIG. 3A.

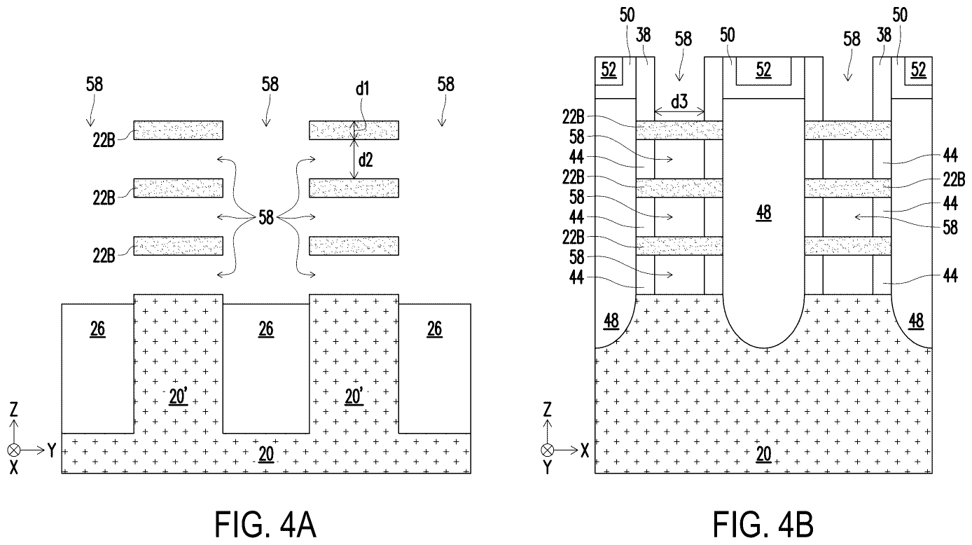

Referring to FIG. 4A and FIG. 4B, the first semiconductor layers 22A (referred to as sacrificial layers) are removed and the recesses 58 are further formed between the second semiconductor layers 22B and the gate spacers 38. In some embodiments, the first semiconductor layers 22A are removed by performing an isotropic etching process such as a wet etching process using etchants which are selective to the materials of the first semiconductor layers 22A, while the second semiconductor layers 22B, the substrate 20, the STI regions 26 remain relatively un-etched as compared to the first semiconductor layers 22A. For example, the first semiconductor layers 22A include SiGe, and the second semiconductor layers 22B include Si or silicon carbide (SiC), etchants or reactants such as tetra methyl ammonium hydroxide (TMAH), and/or ammonium hydroxide (NH₄OH) is used to remove the first semiconductor layers 22A.

Referring to FIG. 4A and FIG. 4B, the second semiconductor layers 22B are vertically stacked over a protruding fin of a substrate. In some embodiments, the second semiconductor layers 22B extending in parallel are spaced apart from one another (referred to as channel layers). In some embodiments, each second semiconductor layers 22B has a thickness d1 in a range of about 3 nm to about 10 nm, as shown in FIG. 4A. In some embodiments, two adjacent second semiconductor layers 22B are separated from each other by a sheet-sheet distance d2 in a range of about 7 nm to about 15 nm, as shown in FIG. 4A. In some embodiments, a distance between the inner sidewalls of the inner spacers 44 is in a range of about 8 nm to about 30 nm, as shown in FIG. 4B.

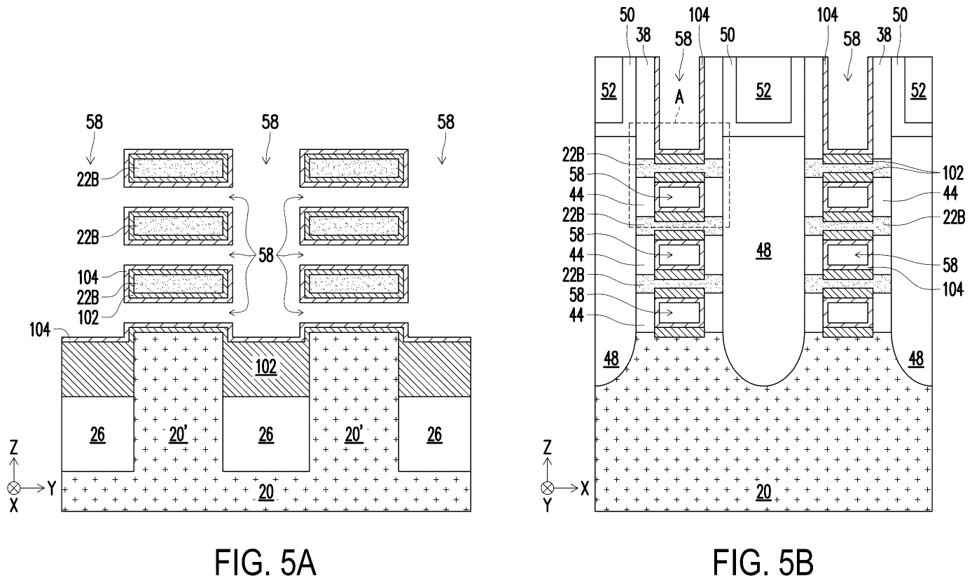

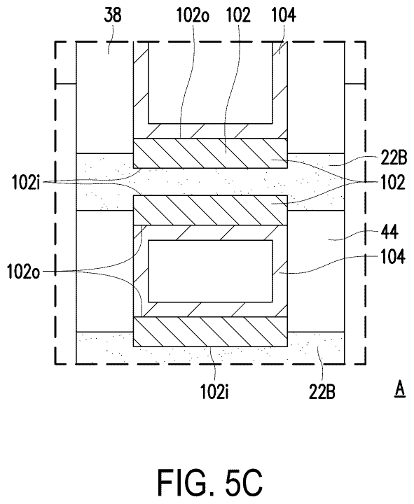

Referring to FIG. 5A through FIG. 5B, within the recesses 58, interfacial dielectric layers 102 are formed on the surface of the second semiconductor layers 22B (referred to as channel layers) and the protruding fins 20′ of the substate 20. In some embodiments, the revealed portions of the second semiconductor layers 22B and the substate 20 are oxidized to form the interfacial dielectric layers 102. In some embodiments, the interfacial dielectric layer 102 is disposed on and wraps around the second semiconductor layers 22B, and covers a top surface and sidewalls of the protruding fins 20′ of the substrate 20. In some embodiments, the interfacial dielectric layer 102 covers sidewalls of the protruding fins 20′ of the substrate 20 and joined with the STI regions 26, as shown in FIG. 5A. In some embodiments, the interfacial dielectric layer 102 joined to the STI regions 26 is without an interface therebetween. In some embodiments, no clear interface is existed between the interfacial dielectric layer 102 and the STI regions 26.

FIG. 5C is an enlarged view of a region A of FIG. 5B. Referring to FIG. 5A through FIG. 5C, the interfacial dielectric layer 102 may be formed by consuming portions of the semiconductor material, and the interfacial dielectric layer 102 includes inner surface 102i facing and extending into the second semiconductor layers 22B or the protruding fins 20′, and outer surface 102o opposite to the inner surface 102i and protruding from the second semiconductor layers 22B or the protruding fins 20′, as shown in FIG. 5C. In some embodiments, a portion of the interfacial dielectric layer 102 is embedded in the second semiconductor layers 22B or the substate 20, and the other portion of the interfacial dielectric layer 102 protrudes from the second semiconductor layers 22B or the substate 20. In some embodiments, the interfacial dielectric layer 102 covers the inner sidewalls of the inner spacers 44. In some embodiments, the interfacial dielectric layer 102 is in direct contact with the second semiconductor layers 22B, the protruding fins 20′ of the substate 20 and the inner spacers 44.

Referring to FIG. 5A through FIG. 5C, the interfacial dielectric layer 102 includes a dielectric material such as silicon oxide. In some embodiments, the interfacial dielectric layer 102 is formed by a thermal oxidation process. In some embodiments, the interfacial dielectric layer 102 is formed by using a wet chemical oxidation. For example, the wet chemical oxidation includes using an aqueous solution containing sulfuric acid (H₂SO₄) and hydrogen peroxide (H₂O₂), ozone water, an aqueous solution containing NH₄OH and H₂O₂, or an aqueous solution containing HCl and H₂O₂. In some embodiments, the interfacial dielectric layer 102 has a thickness in a range of about 0.5 nm to about 2 nm.

Referring to FIG. 5A through FIG. 5C, a high-k dielectric layer 104 is formed on interfacial dielectric layer 102 and the inner sidewalls of the inner spacers 44. A combination of the interfacial dielectric layer 102 and the high-k dielectric layer 104 is referred to as a composite dielectric layer. In some embodiments, the high-k dielectric layer 104 is in direct contact with the interfacial dielectric layer 102 and the inner sidewalls of the inner spacers 44. In some embodiments, the high-k dielectric layer 104 wraps around and covers the interfacial dielectric layer 102, as shown in FIG. 5A. In some embodiments, the high-k dielectric layer 104 covers the interfacial dielectric layer 102 and the revealed inner sidewalls of the inner spacers 44, the high-k dielectric layer 104 is formed conformally covering the adjacent interfacial dielectric layers 102 and the inner sidewalls of the inner spacers 44, and the high-k dielectric layer 104 encircles the sidewalls of the recess 58 (in ring-shapes from cross-sectional views) between adjacent interfacial dielectric layers 102, as shown in FIG. 5B. In some embodiments, from the cross-sectional view in FIG. 5B, the adjacent interfacial dielectric layers 102 are sandwiched between the high-k dielectric layer 104 located at opposite sides of the second semiconductor layers 22B.

Referring to FIG. 5A through FIG. 5C, the high-k dielectric layer 104 includes one or more dielectric layers. For example, the high-k dielectric layer 104 includes hafnium oxide (HfOx), aluminum oxide (AlOx), zirconium oxide (ZrOx), lanthanum oxide (LaOx), zinc oxide (ZnOx), other suitable high-k dielectric materials, and/or combinations thereof. In some embodiments, the high-k dielectric layer 104 is formed by CVD, ALD, or any suitable method. In some embodiments, the high-k dielectric layer 104 has a thickness in a range of about 1 nm to about 2 nm.

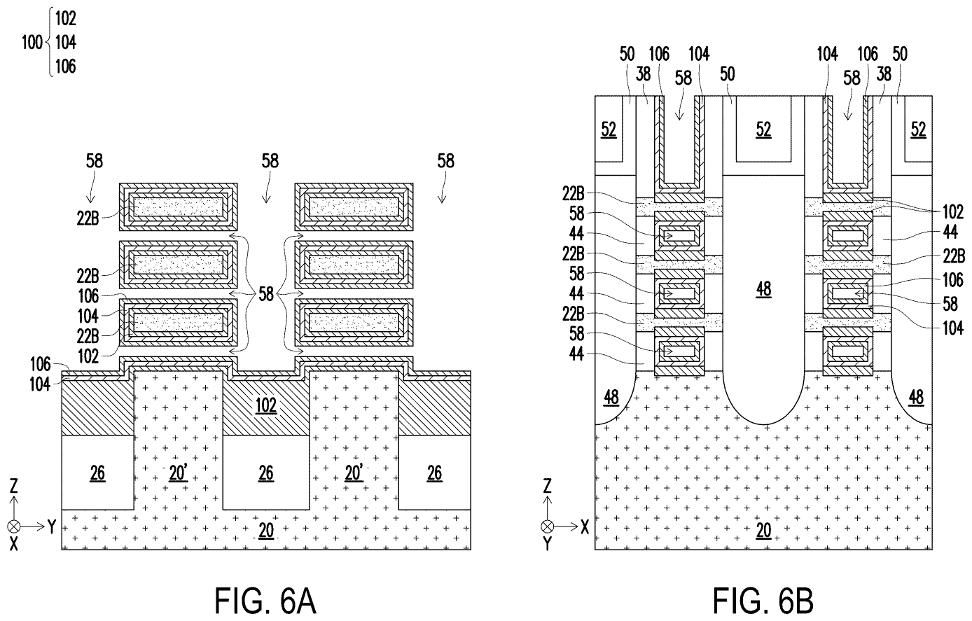

Referring to FIG. 6A and FIG. 6B, a cap layer 106 is formed on and covers the high-k dielectric layer 104, so that a composite stack 100 including the interfacial dielectric layer 102, the high-k dielectric layer 104 and the cap layer 106 is formed. In some embodiments, the cap layer 106 is in direct contact with the high-k dielectric layer 104. In some embodiments, the cap layer 106 wraps around and covers the high-k dielectric layer 104. In some embodiments, the high-k dielectric layer 104 is sandwiched with the cap layer 106 and the interfacial dielectric layer 102. In some embodiments, the cap layer 106 is formed conformally covering the high-k dielectric layer 104, and the cap layer 106 encircles the sidewalls of the recess 58 (in ring-shapes from cross-sectional views) within the high-k dielectric layer 104, as shown in FIG. 6B.

Referring to FIG. 6A and FIG. 6B, in some embodiments, the cap layer 106 is formed of a material containing metal silicide (i.e. metal silicide containing material). For example, the material of the cap layer 106 includes titanium silicide nitride (TiSiN), tantalum aluminum silicide carbide (TaSiAlC), titanium aluminum silicide carbide (TiAlSiC) and/or combinations thereof. In some embodiments, the cap layer 106 is formed by atomic layer deposition (ALD), chemical vapor deposition (CVD) and/or other suitable methods. In some embodiments, the cap layer 106 has a thickness in a range of about 0.5 nm to about 2 nm. In some embodiments, a ratio of the thickness of the cap layer 106 to the sheet-sheet distance d2 is about 1:3 to 1:30.

In some embodiments, higher silicon content (Si content) of the metal silicide containing material leads to the expansion of the metal lattice. For example, when the Si content of the cap layer 106 ranges from about 5 at % to about 40 at %, the expansion of the metal lattice of the cap layer 106 is induced. As a result, the semiconductor layers 22B are strained by the cap layer 106, and the expanded lattice of the cap layer 106 applies a strain on the individual semiconductor layer 22B (referred to as the channel layer containing Si) to cause a compressive stress ranging from about −0.1 GPa to about −3 GPa within channel layer in a thickness direction (Szz) of the channel layer (For example, the thickness direction is z direction shown in FIG. 6A and FIG. 6B) and to cause a tensile stress ranging from about 0.1 GPa to about 3 GPa within the channel layer in a length direction (Sxx) of the channel layer (For example, the length direction is x direction shown in FIG. 6A and FIG. 6B) simultaneously. The strain applied on the channel layer also increase the lattice constant of Si of the channel layer ranging from about +0.1% to about +1.5%. As the channel layers are strained by forming the cap layer around them, the carrier mobility and conductivity of the channel layer(s) are enhanced. For example, the mobility gain is in a range of about 4% to about 300%. The performance of the semiconductor device (especially for NFET) is improved. The additional cap layer 106 functions as a stressor to the channel layer(s). In addition, the additional strain caused by the cap layer 106 in combination with the strain from the S/D regions lead to enhanced strain effects in the channel layers. Under the circumstances that the epitaxy growth of the S/D regions is imperfect, the formation of the cap layer as additional stressor can counterbalance such issue. As a result, the performance of the semiconductor device is improved.

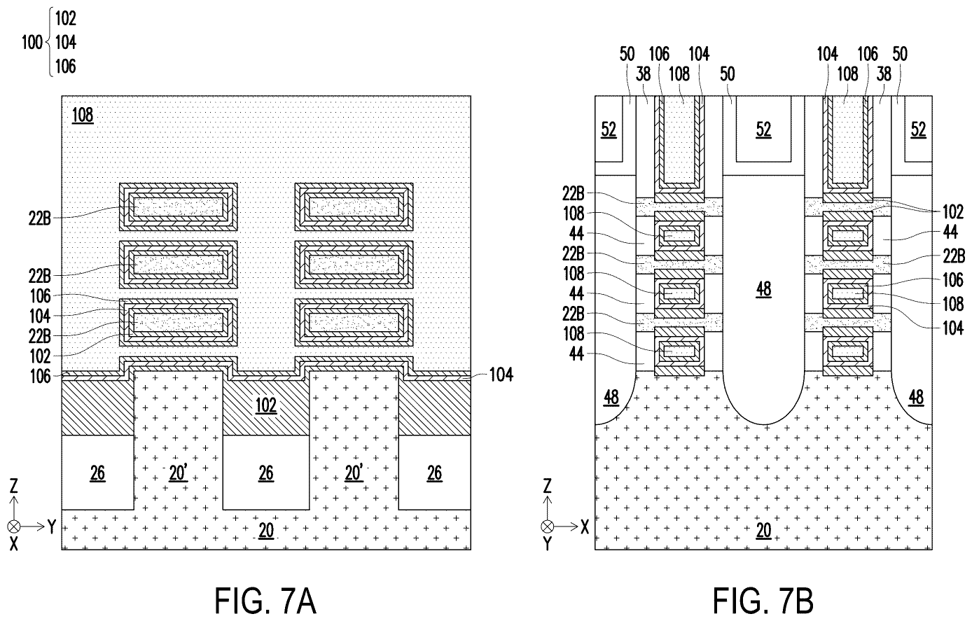

Referring to FIG. 7A and FIG. 7B, gate electrode 108 is formed on the cap layer 106, covers the cap layer 106, wraps around the semiconductor layers 22B, and fill the remaining portions of recesses 58, as shown in FIG. 6A and FIG. 6B. In some embodiments, the gate electrode 108 is separated from the second semiconductor layers 22B through the composite stack 100. In some embodiments, the composite stack 100 is sandwiched between the semiconductor layers 22B and the gate electrode 108. In some embodiments, the gate electrode 108 is in direct contact with the cap layer 106. In some embodiments, the gate electrode 108 is separated from the high-k dielectric layer 104 through the cap layer 106. In some embodiments, the cap layer 106 is sandwiched between the gate electrode 108 and the high-k dielectric layer 104.

Referring to FIG. 7A and FIG. 7B, the gate electrode 108 includes a metal-containing material such as titanium nitride (TiN), tantalum nitride (TaN), titanium aluminide (TiAl), titanium aluminum carbide (TiAlC), tantalum aluminum carbide (TaAlC), tungsten carbonitride (WCN), molybdenum (Mo), any suitable material, combinations thereof, and/or multilayers thereof. For example, although in FIGS. 7A and 7B, a single layer is illustrated to represent the gate electrode 108, the gate electrode 108 may include any number of the gate electrode layers. In some embodiments, the gate electrode 108 is formed by a deposition process such as CVD, ALD, or any suitable method. In some embodiments, the gate electrode 108 has a thickness in a range of about 1 nm to about 5 nm. After the deposition process is performed, a planarization process such as a CMP process or a mechanical grinding process is performed to remove the excess material of the gate electrode 108 until reaching a desired thickness.

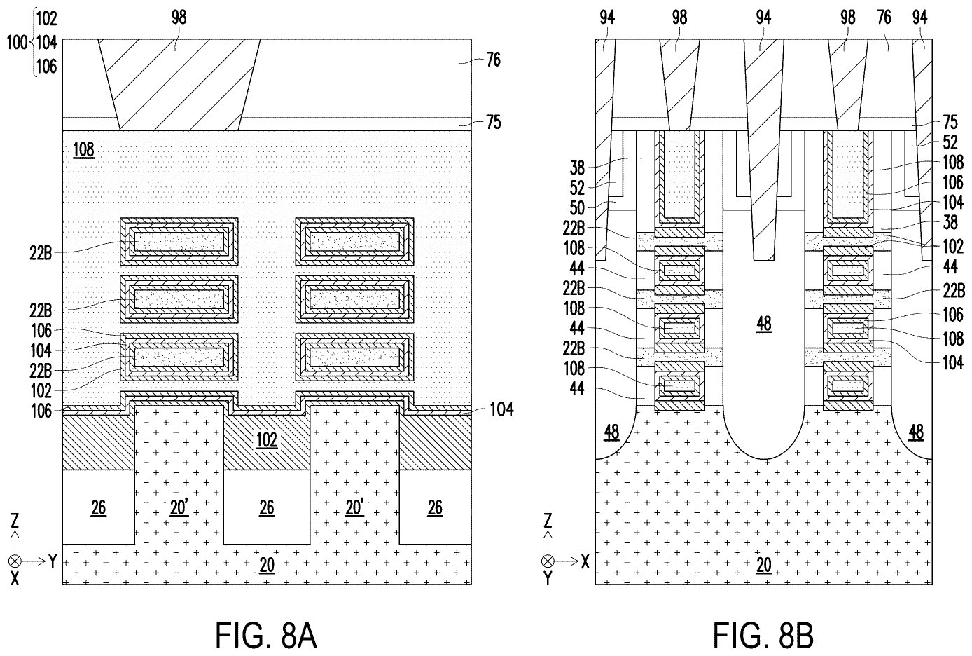

Referring to FIG. 8A and FIG. 8B, an etch stop layer 75 is formed over the gate electrode 108, as shown in FIG. 8A, and formed over the ILD 52, the CESL 50, the gate spacers 38, the high-k dielectric layer 104, the cap layer 106, and the gate electrode 108, as shown in FIG. 8B. In some embodiments, the etch stop layer 75 includes silicon nitride, silicon carbide, silicon oxynitride, aluminum oxide, aluminum nitride, or the like, or multilayers thereof. In some embodiments, the etch stop layer 75 is formed through ALD, CVD, PECVD, or the like.

Referring to FIG. 8A and FIG. 8B, an ILD 76 is formed over the etch stop layer 75. In some embodiments, the ILD 76 includes a dielectric material such as silicon oxide, PSG, BSG, BPSG, USG, or the like. In some embodiments, the ILD 76 is formed by FCVD, CVD, PECVD, or the like.

Referring to FIG. 8A and FIG. 8B, the ILD 76, the etch stop layer 75, the ILD 52, the CESL 50 and the source/drain regions 48 are etched to form etching openings for subsequently formed source/drain contact plugs 94 and gate contact plugs 98. In some embodiments, the etching openings are formed by any suitable etching process such as a dry etching process or a wet etching process. In some embodiments, the etching openings are filled with one or more conductive material such as Ti, TiN, W, Co, or the like, and then a planarization process is performed to form the source/drain contact plugs 94 and the gate contact plugs 98. In some embodiments, the source/drain contact plugs 94 are in contact with and electrically connected to the source/drain regions 48 respectively. In some embodiments, the gate contact plugs 98 are in contact with and electrically connected to the gate electrode 108 respectively.

In some embodiments, although in FIGS. 8A and 8B, front-side contact plugs such as the source/drain contact plugs 94 and the gate contact plugs 98 are illustrated, back-side contact plugs opposite to the front-side contact plugs may be included to penetrate through the substrate 20 and the source/drain regions 48. The back-side contact plugs electrically connect to and are in contact with the source/drain regions 48. In some embodiments, the front-side contact plugs and/or the back-side contact plugs are configured to any suitable configuration.

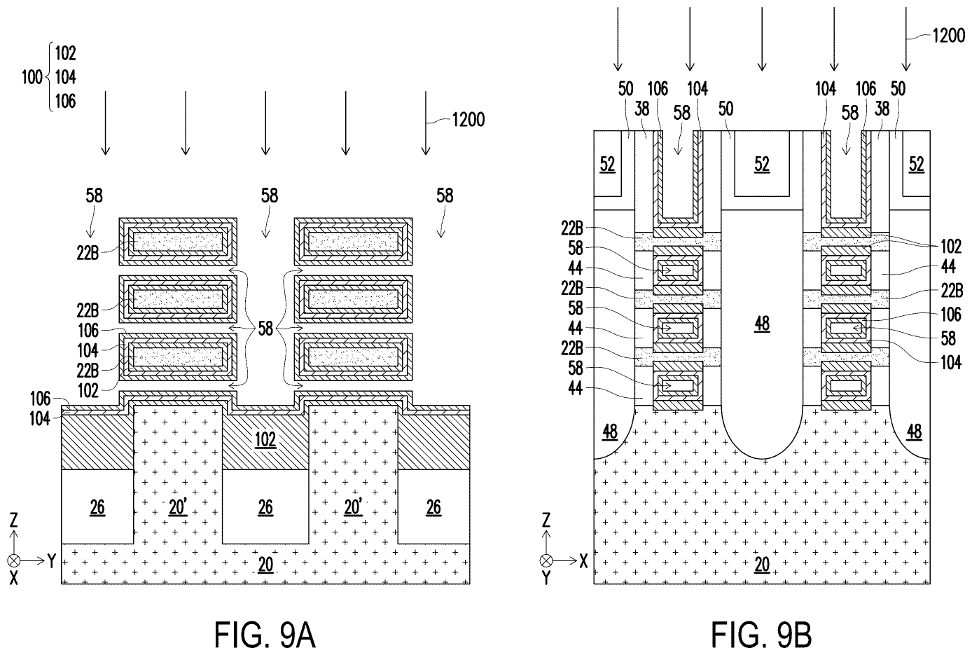

FIG. 9A through FIG. 12B are schematic cross-sectional views schematically illustrate various stages of a process for fabricating a Gate All-Around (GAA) transistor and contact plugs in accordance with some embodiments of the present disclosure. Except for the further description, the definition of the reference symbols and labeled representations are the same as FIG. 1A through FIG. 8B, and will not be repeated herein.

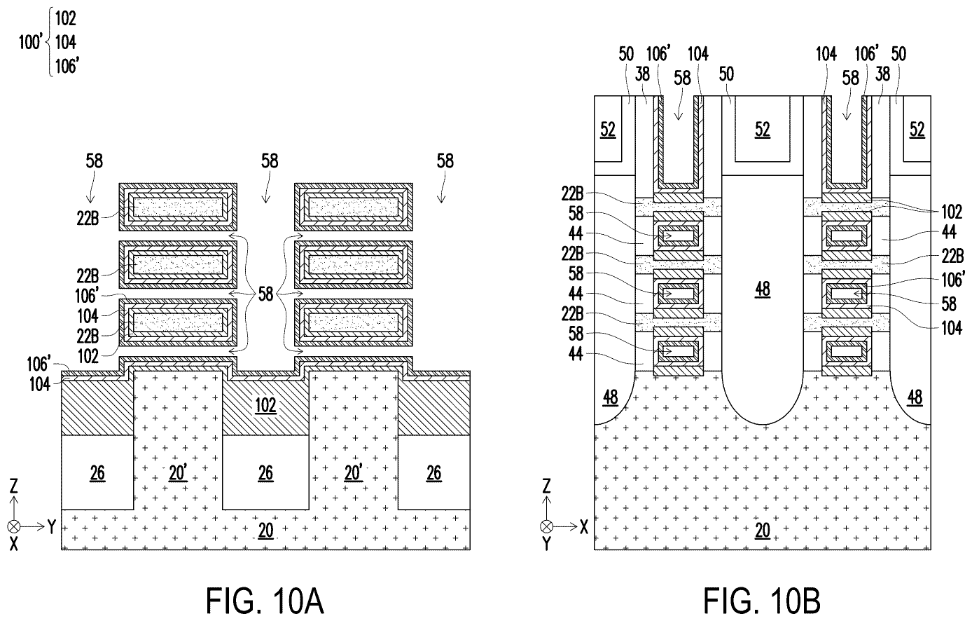

Referring to FIG. 9A and FIG. 9B, different from the process steps illustrated in FIG. 6A and FIG. 6B, an additional oxygen boosting process 1200 is performed after the formation of the cap layer 106. In some embodiments, the material of the cap layer 106 includes TiN, TiSiN, TaSiAlC, TiAlSiC and/or combinations thereof. In some embodiments, the oxygen boosting process 1200 is performed on the cap layer 106 to form a treated cap layer 106′, as shown in FIG. 10A and FIG. 10B. By applying the oxygen boosting process 1200, oxygen is introduced into the treated cap layer 106′, and the treated cap layer 106′ is endowed with a high oxygen content (enriched with oxygen). In some embodiments, when an oxygen (O) content of the cap layer 106′ ranges from about 30 at % to about 50 at %, the expansion of the lattice of the cap layer 106′ is also induced. The oxygen enriched cap layer 106′ applies a strain to the semiconductor layers 22B, and the semiconductor layers 22B are strained by the treated cap layer 106′ with a compressive stress ranging from about −0.1 GPa to about −3 GPa within the semiconductor layer 22B (referred to as the channel layer containing Si) in the thickness direction (Szz) of the channel layer and with a tensile stress ranging from about 0.1 GPa to about 3 GPa within the semiconductor layer 22B in the length direction (Sxx) of the channel layer simultaneously. The strain applied on the semiconductor layers 22B (i.e. channel layers) also increases the lattice constant of Si in the channel layers, from about +0.1% to about +1.5%. As the channel layers are strained by forming the cap layer around them, the carrier mobility and conductivity of the channel layer(s) are enhanced. As a result, the performance of the semiconductor device (especially for NFET) is improved. In some embodiments, the oxygen boosting process 1200 boosts the oxygen (O) content in the cap layer 106′ to possess the higher intrinsic stress relative to the cap layer 106 before the oxygen boosting process.

Referring to FIG. 9A and FIG. 9B, the oxygen boosting process 1200 includes performing a dry oxidation process or performing a wet chemical oxidation process. For example, the dry oxidation includes applying a mixture of O₂ gas and N₂ gas to the cap layer 106 under a temperature from about 300° C. to about 1000° C. A ratio of O₂ gas to the mixture of O₂ gas and N₂ gas is in a range of 0.1% to about 10%. For example, the dry oxidation includes applying an O₂/N₂ plasma to the cap layer 106. A ratio of O₂ plasma to the O₂/N₂ plasma is in a range of higher than 0 to about 10%. For example, the wet chemical oxidation includes applying an aqueous solution to the cap layer 106 in a temperature range of room temperature to about 100° C. The aqueous solution contains at least one of deionized water with ozone, hydrogen peroxide (H₂O₂) and deionized water with dissolved carbon dioxide, or a mixture thereof.

Referring to FIG. 10A and FIG. 10B, the cap layer 106′ is formed on each high-k dielectric layer 104, and a composite stack 100′ is also formed. In some embodiments, the composite stack 100′ includes the interfacial dielectric layer 102, the high-k dielectric layer 104 and cap layer 106′. In some embodiments, the cap layer 106′ is in direct contact with the high-k dielectric layer 104. In some embodiments, the cap layer 106′ wraps around the high-k dielectric layer 104, and covers the high-k dielectric layer 104, as shown in FIG. 10A. In some embodiments, the cap layer 106′ covers the high-k dielectric layer 104, then a ring shape structure of the cap layer 106′ is formed within the ring shape structure of the high-k dielectric layer 104, and the ring shape structure of the high-k dielectric layer 104 encircles the recess 58 between adjacent interfacial dielectric layers 102, as shown in FIG. 10B. In some embodiments, the cap layer 106′ has a thickness in a range of about 0.5 nm to about 2 nm. In some embodiments, a ratio of the thickness of the cap layer 106′ to the sheet-sheet distance d2 is about 1:3 to 1:30.

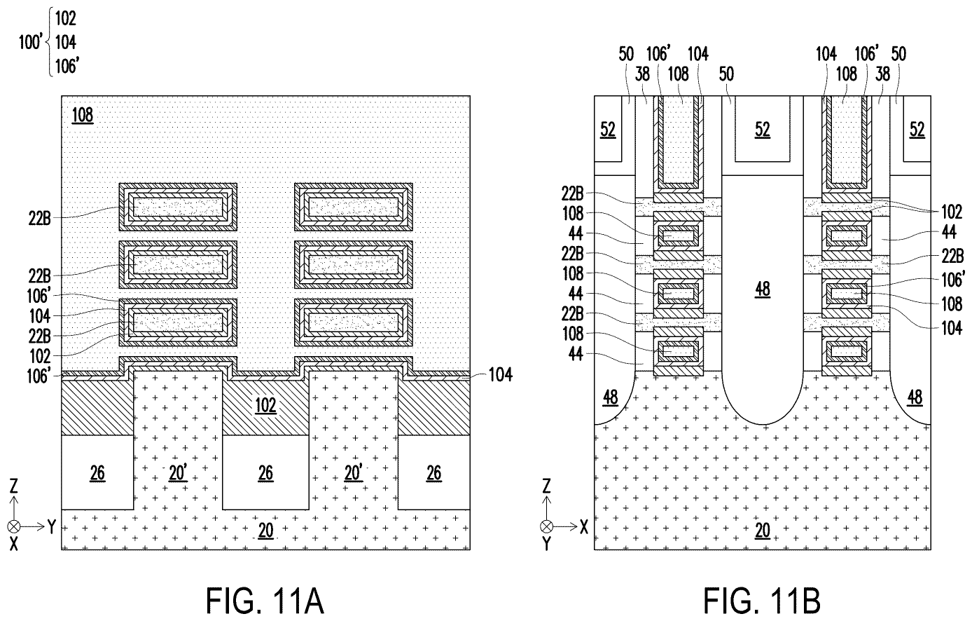

Referring to FIG. 11A and FIG. 11B, the gate electrode 108 are formed on the cap layer 106′ and cover the cap layer 106′, and fill the remaining portions of recesses 58, as shown in FIG. 10A and FIG. 10B. In some embodiments, the gate electrode 108 is in direct contact with the cap layer 106′. In some embodiments, the cap layer 106′ is sandwiched between the gate electrode 108 and the high-k dielectric layer 104. In some embodiments, the gate electrode 108 is separated from the high-k dielectric layer 104 through the cap layer 106′. The formation and the material of the gate electrode 108 are the same as the gate electrode 108 described in the previous contexts.

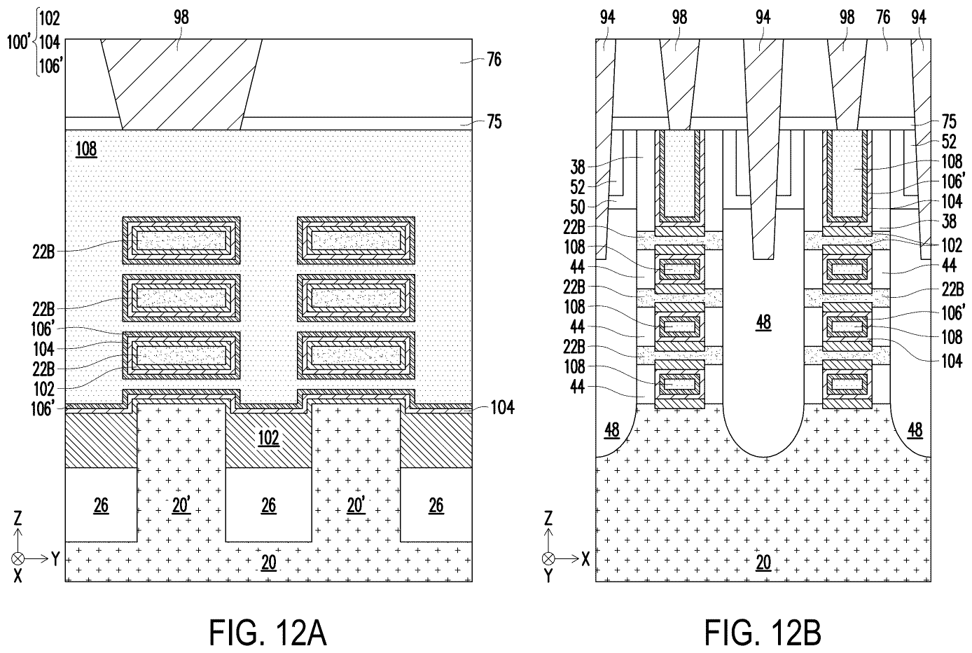

Referring to FIG. 12A and FIG. 12B, the formation and the material of the etch stop layer 75, the ILD 76, the source/drain contact plugs 94 and the gate contact plugs 98, are the same as the etch stop layer 75, the ILD 76, the source/drain contact plugs 94 and the gate contact plugs 98 described in the previous contexts. In some embodiments, the source/drain contact plugs 94 are in contact with and electrically connected to the source/drain regions 48 respectively. In some embodiments, the gate contact plugs 98 are in contact with and electrically connected to the gate electrode 108 respectively.

In some embodiments, although in FIGS. 12A and 12B, front-side contact plugs such as the source/drain contact plugs 94 and the gate contact plugs 98 are illustrated, back-side contact plugs opposite to the front-side contact plugs may be included to penetrate through the substrate 20 and the source/drain regions 48. The back-side contact plugs electrically connect to and are in contact with the source/drain regions 48. In some embodiments, the front-side contact plugs and/or the back-side contact plugs are configured to any suitable configuration.

In accordance with some embodiments of the disclosure, a method of forming a semiconductor device is provided. Semiconductor layers are formed and vertically stacked over a protruding fin of a substrate. Source/drain regions are formed on the substrate and at opposite sides of semiconductor layers. A composite dielectric layer is formed on and around the semiconductor layers. A cap layer is formed on and around the composite dielectric layer to cause a compressive stress within the semiconductor layers in a thickness direction (Szz) of the semiconductor layers and a tensile stress within the semiconductor layers in a length direction (Sxx) of the semiconductor layers. A gate electrode is formed on the cap layer.

In accordance with some embodiments of the disclosure, a semiconductor device is provided. The semiconductor device includes semiconductor layers vertically stacked over a protruding fin of a substrate, source/drain regions disposed on the substrate and located at opposite sides of the semiconductor layers, a composite dielectric layer disposed on and wrapping around the semiconductor layers and a cap layer disposed on and around the composite dielectric layer and the semiconductor layers. The semiconductor layers extending in parallel are spaced apart from one another. The composite dielectric layer includes an interfacial dielectric layer and a high-k dielectric layer on the interfacial dielectric layer. The semiconductor layers are strained by the cap layer with a compressive stress within the semiconductor layers in a thickness direction (Szz) of the semiconductor layers and a tensile stress within the semiconductor layers in a length direction (Sxx) of the semiconductor layers. The semiconductor device further includes a gate electrode disposed on the cap layer.

In accordance with some embodiments of the disclosure, a method of forming a semiconductor device is provided. Semiconductor layers are formed and vertically stacked over a protruding fin of a substrate. Source/drain regions are formed on the substrate and at opposite sides of semiconductor layers. A composite dielectric layer is formed on and around the semiconductor layers. A cap layer is formed on and around the composite dielectric layer to apply a strain to the semiconductor layers, wherein the semiconductor layers are compressed in a thickness direction (Szz) of the semiconductor layers and are tensioned in a length direction (Sxx) of the semiconductor layers. A gate electrode is formed on the cap layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming semiconductor layers vertically stacked over a protruding fin of a substrate, wherein the semiconductor layers extending in parallel are spaced apart from one another;
forming source/drain regions on the substrate and at opposite sides of the semiconductor layers;
forming a composite dielectric layer on and around the semiconductor layers;
forming a cap layer on and around the composite dielectric layer and around the semiconductor layers to cause a compressive stress within the semiconductor layers in a thickness direction (Szz) of the semiconductor layers and a tensile stress within the semiconductor layers in a length direction (Sxx) of the semiconductor layers; and
forming a gate electrode on the cap layer and around the semiconductor layers.

2. The method of claim 1, wherein the cap layer is formed of titanium silicide nitride (TiSiN), tantalum aluminum silicide carbide (TaSiAlC), titanium aluminum silicide carbide (TiAlSiC) or a combination thereof, and the cap layer has a silicon content ranging from about 5 at % to about 40 at %.

3. The method of claim 1, wherein the cap layer is formed of titanium nitride (TiN), titanium silicide nitride (TiSiN), tantalum aluminum silicide carbide (TaSiAlC), titanium aluminum silicide carbide (TiAlSiC) or a combination thereof, and the method further comprises performing an oxygen boosting process to the cap layer to form a treated cap layer with an oxygen content ranging from about 30 at % to about 50 at %.

4. The method of claim 3, wherein performing the oxygen boosting process to the cap layer comprises applying a plasma treatment with a gas containing oxygen.

5. The method of claim 1, wherein forming semiconductor layers comprises forming silicon through an epitaxy growth process, and a lattice constant of the silicon in the semiconductor layers is increased about 0.1% to about 1.5% after forming the cap layer around the semiconductor layers.

6. The method of claim 5, wherein the compressive stress ranges from about −0.1 GPa to about −3 GPa in the thickness direction (Szz) of the semiconductor layers, and the tensile stress ranges from about 0.1 GPa to about 3 GPa in the length direction (Sxx) of the semiconductor layers.

7. The method of claim 1, wherein forming the composite dielectric layer comprises:
forming an interfacial dielectric layer on and around the semiconductor layers; and
forming a high-k dielectric layer on and around the interfacial dielectric layer.

8. A semiconductor device, comprising:
semiconductor layers vertically stacked over a protruding fin of a substrate, wherein the semiconductor layers extending in parallel are spaced apart from one another;
source/drain regions, disposed on the substrate and located at opposite sides of the semiconductor layers;
a composite dielectric layer, disposed on and wrapping around the semiconductor layers, wherein the composite dielectric layer includes an interfacial dielectric layer and a high-k dielectric layer on the interfacial dielectric layer;
a cap layer disposed on and around the composite dielectric layer and the semiconductor layers, wherein the semiconductor layers are strained by the cap layer with a compressive stress within the semiconductor layers in a thickness direction (Szz) of the semiconductor layers and a tensile stress within the semiconductor layers in a length direction (Sxx) of the semiconductor layers; and
a gate electrode, disposed on the cap layer and wrapping around the semiconductor layers.

9. The semiconductor device of claim 8, wherein the cap layer includes titanium silicide nitride (TiSiN), tantalum aluminum silicide carbide (TaSiAlC), titanium aluminum silicide carbide (TiAlSiC) or a combination thereof, and the cap layer has a silicon (Si) content ranging from about 5 at % to about 40 at %.

10. The semiconductor device of claim 8, wherein the cap layer includes titanium nitride (TiN), titanium silicide nitride (TiSiN), tantalum aluminum silicide carbide (TaSiAlC), titanium aluminum silicide carbide (TiAlSiC) or a combination thereof, and the cap layer is enriched with oxygen with an oxygen (O) content ranging from about 30 at % to about 50 at %.

11. The semiconductor device of claim 8, wherein the high-k dielectric layer is separated from the gate electrode through the cap layer, and the cap layer is in contact with the high-k dielectric layer and the gate electrode.

12. The semiconductor device of claim 8, wherein the composite dielectric layer covers a top surface and sidewalls of the protruding fin of the substrate.

13. A method of forming a semiconductor device, comprising:
forming semiconductor layers vertically stacked over a protruding fin of a substrate, wherein the semiconductor layers extending in parallel are spaced apart from one another;
forming source/drain regions on the substrate and at opposite sides of semiconductor layers;
forming a composite dielectric layer on and around the semiconductor layers;
forming a cap layer on and around the composite dielectric layer and around the semiconductor layers to apply a strain to the semiconductor layers, wherein the semiconductor layers are compressed in a thickness direction (Szz) of the semiconductor layers and are tensioned in a length direction (Sxx) of the semiconductor layers; and
forming a gate electrode on the cap layer and around the semiconductor layers.

14. The method of claim 13, wherein the cap layer is formed of a material different from that of the composite dielectric layer.

15. The method of claim 14, wherein the cap layer is formed of titanium silicide nitride (TiSiN), tantalum aluminum silicide carbide (TaSiAlC), titanium aluminum silicide carbide (TiAlSiC) or a combination thereof, and the cap layer has a silicon content ranging from about 5 at % to about 40 at %.

16. The method of claim 14, wherein the cap layer is formed of titanium nitride (TiN), titanium silicide nitride (TiSiN), tantalum aluminum silicide carbide (TaSiAlC), titanium aluminum silicide carbide (TiAlSiC) or a combination thereof, and the method further comprises performing an oxygen boosting process to the cap layer to form a treated cap layer with an oxygen content ranging from about 30 at % to about 50 at %.

17. The method of claim 16, wherein performing the oxygen boosting process to the cap layer comprises applying a plasma treatment with a gas containing oxygen.

18. The method of claim 14, wherein forming semiconductor layers comprises forming silicon through an epitaxy growth process, and a lattice constant of the silicon in the semiconductor layers is increased about 0.1% to about 1.5% after forming the cap layer around the semiconductor layers.

19. The method of claim 18, wherein the semiconductor layers are strained with a compression stress ranging from about −0.1 GPa to about −3 GPa in a thickness direction (Szz) of the semiconductor layers, and with a tension stress ranging from about 0.1 GPa to about 3 GPa in a length direction (Sxx) of the semiconductor layers.

20. The method of claim 14, wherein the cap layer is formed with a thickness ranging from about 0.5 nm to about 2 nm.
